(19) United States
(12) Patent Application Publication
(10) Pub. No.: US 2025/0328071 A1
(43) Pub. Date: Oct. 23, 2025

(54) BORON NITRIDE NANOTUBE PELLICLES

(71) Applicant: BNNT, LLC, Newport News, VA (US)

(72) Inventors: Kevin C. JORDAN, Newport News, VA (US); Riley M. KEETER, Newport News, VA (US); Eric R. KENNEDY, Newport News, VA (US); Mohammad H. KIRMANI, Newport News, VA (US); Valerie N. ROBERTSON, Newport News, VA (US); Lyndsey R. SCAMMELL, Newport News, VA (US); Michael W. SMITH, Newport News, VA (US); R. Roy WHITNEY, Newport News, VA (US)

(21) Appl. No.: 18/865,246

(22) PCT Filed: May 12, 2023
(86) PCT No.: PCT/US2023/022014

§ 371 Date: Nov. 12, 2024

Related U.S. Application Data
(60) Provisional application No. 63/341,395, filed on May 12, 2022.

(51) Int. Cl. G03F 1/62; C01B 21/064

(52) U.S. Cl. CPC G03F 1/62; C01B 21/0648; C01P 2004/03; C01P 2004/13

(57) ABSTRACT

Described herein are thin-film BNNT materials, and methods for making the same. Such materials are especially useful for forming BNNT-based pellicles used in, e.g., Extreme Ultraviolet (EUV) lithographic processes. BNNTs have thresholds for thermal stability and chemical reactions that are above the reaction temperatures associated with EUV lithography and the gases and plasmas formed therein, and in addition, the BNNT-based pellicles can be heat treated to temperatures that will outgas or otherwise remove contaminants that may collect on the pellicles from gases and plasmas utilized in the lithographic processes. BNNTs are have favorable transmissivity and also provide excellent thermal conductivity, which may be advantageous for reducing undesirable temperature increases during processing. Thin-film BNNT materials described herein have the mechanical and tensile strengths to self-support, and withstand lithography processes without mechanical failure.

### STATEMENT REGARDING GOVERNMENT SUPPORT

None.

### FIELD OF THE INVENTION

The present disclosure relates to boron nitride nanotube (BNNT) pellicles.

### BACKGROUND—INTRODUCTION

High quality, purified BNNTs, i.e., a few-wall (e.g. 1-10 walls, and mostly 2-3 walls) material that is predominantly BNNT, with a minimal amount of boron particulates, amorphous boron nitride (a-BN), BN nanocages, BN nanosheets, and any other non-BNNT materials containing boron nitride, have a range of desirable properties for numerous applications. For example, BNNTs survive in air up to 900° C. and in inert environment to over 2000° C. In addition, BNNTs have minimal chemical reactions with most materials, are electrically insulating, and have high thermal conductivity.

Pellicles are utilized in systems where some materials or particulates in one region need to be kept from entering another region. An example is in the lithographic systems used in the manufacture of integrated electronic circuits. These systems typically pass light from one region to the region where the photochemical reactions take place. The pellicle is required to both let the light pass through while preventing the particulates from reaching the reaction region. Frequently there are multiple exchanges of gas between the regions and sometimes plasmas are involved. Current pellicles are formed from graphene, though a variety of materials have been developed for making pellicles, including carbon nanotube (CNT) based pellicles. But most current pellicle materials, including CNT pellicles, have limited lifetimes due to reactions with the gases and/or plasmas that are involved in the processes, and also the process temperatures and reactions with free radicals produced during lithography. A variety of coatings have been applied to pellicle materials with some success but the have not achieved the desired levels of performance. Shorter wavelength lithographic processes are promising, in terms of increasing the transistor density, but will require significant advancements in pellicle technology.

What is needed, then, are new materials for superior pellicles. Such materials must have sufficient mechanical, temperature, and chemical stability to function during lithographic processes, without loss of shape, deterioration of transmissivity, or adverse reaction to free radicals that form during processing.

### BRIEF SUMMARY

Described herein are thin-film BNNT materials, including BNNT-based pellicles, and methods for making the same. The advantage of BNNT-based pellicles is that the BNNTs have thresholds for thermal stability and chemical reactions that are above the reaction temperatures associated with lithographic processes and the gases and plasmas formed therein, and in addition, the BNNT pellicles can be heat treated to temperatures that will outgas or otherwise remove contaminants that may collect on the pellicles from gases and plasmas utilized in the lithographic processes. BNNTs also provide excellent thermal conductivity, which may be advantageous for reducing undesirable temperature increases during processing.

This disclosure describes a method to fabricate films and membranes composed of BNNTs, and articles made from such BNNT materials. The nanotubes in some embodiments are preferentially aligned in the plane of the article. These films have high transparency to visible, ultraviolet (UV), and extreme UV (EUV) light, such that transmission at these wavelengths is greater than 80% in most embodiments, and greater than 90% in some embodiments. The BNNT in the film may be bundled together to form a network which may result in a self-supporting film, having sufficient tensile strength to serve as, among other uses, a pellicle for lithographic processes. In some embodiments, the areal density of the BNNT film may range from 10⁻⁹ to 10⁻³ g/cm² (1 nanogram to 1 milligram/cm²). In some embodiments, the volumetric density of the film may range from 10⁻³ to 2 g/cm³, (1 milligram to 2 grams/cm³), depending on the desired final properties and configuration of the film. The surface of the film may be flat and smooth for some embodiments, such that the variations in thickness are less than 1% of the average thickness, or for other embodiments may be relatively rough to include variations of up to 50% of the average thickness. Porosity between individual and aggregates or bundles of nanotubes in a thin film BNNT material may be controlled to result in openings in the thin film BNNT material to allow certain species to pass. Thus, the BNNT film may, in some embodiments, be porous to gases and ions including, for example, nitrogen, oxygen, water vapor, hydrogen, chlorides, fluorides, organic chemicals in general, noble gases, etc., where the open area of the film is greater than 50% of the total area of the film.

The thin-film BNNT materials described herein are especially useful as pellicles. An example of where pellicles are utilized is in systems where some materials or particulates in one region need to be kept from entering another region, such as in the lithographic systems used in the manufacture of integrated electronic circuits. These systems typically pass light from one region to the region where the photochemical reactions take place. The pellicle is required to both let the light to pass through and prevent the particulates from reaching the reaction region. Frequently there are multiple exchanges of gas between the regions, and sometimes plasmas are involved. A variety of materials have been developed for making pellicles including carbon nanotube (CNT) based pellicles, but most of the current materials including the CNT-based pellicles have limited lifetimes due to reactions with the gases and/or plasmas that are involved in the processes. There are several advantages of BNNT-based pellicles, such as BNNTs have thresholds for chemical reactions that are above the reactions driven by the gases and plasmas, and BNNT-based pellicles can be heat treated to temperatures that will outgas or otherwise remove contaminants that may collect on the pellicles from gases and plasmas utilized in the lithographic processes.

Described herein are thin film boron nitride nanotube (BNNT) materials that are especially useful for forming pellicles for attaching to photomasks during lithographic printing. Under the present approach, thin film BNNT materials have at least 80 wt. % BNNTs, and over 50% of the BNNTs have 2-walls or 3-walls with an average tube lengths in excess of 1.0 microns. The thin film BNNT material having a film thickness between 0.1 micron and 300 microns. In some embodiments, the thin film BNNT material is at least 95 wt. % BNNTs. In some embodiments, the thin film BNNT material has a film thickness between 0.02 micron and 100 microns. In some embodiments, over 70% of the BNNTs in the thin film BNNT material have 2-walls or 3-walls. In some embodiments, the BNNTs in the thin film BNNT material have an average tube length of at least 1.5 microns. In some embodiments, the thin film BNNT material is self-supporting over an area at least 3 cm in diameter. In some embodiments, the thin film BNNT material is at least 80% optically transparent to visible light, and preferably at least 90% optically transparent to visible light. In some embodiments, the BNNT material has an areal density of between 1 μg/cm² and 500 μg/cm². In some embodiments, the BNNT material has a volume density of between 0.01 g/cm³ and 1 g/cm³. Some embodiments may have, or be formed from, a plurality of layers of BNNT material. The present approach may also take the form of a BNNT-based pellicle comprising a thin film BNNT material of any preceding claim, attached to a frame.

Some embodiments of the present approach may take the form of methods for producing a thin film boron nitride nanotube (BNNT) material. For example, in some embodiments a refined BNNT material is prepared by removing boron particulates from an initial BNNT material; then a purified BNNT material is prepared by removing amorphous boron particles, a-BN, BN nanocages, and BN nanosheets from the refined BNNT material. Next, a BNNT dispersion is formed by dispersing the purified BNNT material in a solvent. An optimized BNNT solution by separating a top fraction or other desired fraction from the BNNT dispersion. Then a thin film of BNNT is formed on a substrate by depositing the optimized BNNT solution on the substrate and removing the solvent.

In some embodiments, removing boron particulates from an initial BNNT material comprises heating the initial BNNT material in a nitrogen and water vapor environment, at a temperature of about 500-650° C. Amorphous boron particles, a-BN, BN nanocages, and BN nanosheets may be removed from the initial BNNT material comprises heating the refined BNNT material to a temperature from 650° C. to 900° C. It should be appreciated that the top fraction or desired fraction will vary and depend on, among other factors, the quality and characteristics of the initial BNNT material and the solvent system used for a given embodiment. Thus, for example, the top fraction may by the top 75% of the volume of the BNNT dispersion in some embodiments, and the top fraction or desired fraction may be the top 5% of the volume of the BNNT dispersion in some embodiments.

The present approach may also take the form of methods for producing a thin film BNNT pellicle. Generally, a BNNT solution may be prepared from (a) a BNNT material having at least 80 wt. % BNNTs, over 50% of the BNNTs have 2-walls or 3-walls and average tube lengths in excess of 1.0 microns, and (b) a solvent. A thin film may be prepared from the BNNT solution, and then the thin film may be mounted for use as a pellicle. These and other embodiments will be apparent through the following description.

### BRIEF DESCRIPTION OF THE DRAWINGS

FIG. 1 shows an image of a refined BNNT puffball, after over 98 wt. % boron particulate removal.

FIG. 2 shows a distribution of high quality BNNT diameters in an embodiment of the present approach.

FIG. 3 shows an SEM of high quality BNNT collected from a solution.

FIG. 4 is an image of a 3-wall BNNT have a 4.5 nm diameter.

FIG. 5 shows a picture taken through a BNNT pellicle mounted on a nylon substrate of some BNNT puffballs in jars along with another jar.

FIG. 6 shows a 3 cm diameter BNNT pellicle with a clear square of plastic holding it in place on a white paper background.

FIG. 7 shows SEM images of a 400 microgram/cm² areal density BNNT-based pellicle.

### DETAILED DESCRIPTION

This disclosure describes BNNT-based thin films and membranes, and methods to fabricate films and membranes composed of BNNTs which are preferentially aligned in the plane of the article. The film has a high transparency to visible, ultraviolet (UV), and extreme UV (EUV) light such that transmission at these wavelengths is greater than 80%. The BNNT in the film may be bundled together to form a network which may result in a self-supporting film. The areal density of the BNNT film may range from 10⁻⁹ to 10⁻³ g/cm² (1 nanogram to 1 milligram/cm²). The volumetric density of the film may range from 10⁻³ to 2 g/cm³, (1 milligram to 2 grams/cm³), depending on the desired final properties of the film. The surface of the film may be flat and smooth such that the variations in thickness are less than 1% of the average thickness, or may be relatively rough to include variations of up to 50% of the average thickness. The BNNT film may be porous to gases and ions including nitrogen, oxygen, water vapor, hydrogen, chlorides, fluorides, organic chemicals in general, noble gases, etc. where the open area of the film is greater than 50% of the total area of the film.

An example of where pellicles are utilized is in systems where some materials or particulates in one region need to be kept from entering another region such as in the lithographic systems used in the manufacture of integrated electronic circuits. These systems typically pass light from one region to the region where the photochemical reactions take place. The pellicle is required to both let the light to pass through while preventing the particulates from reaching the reaction region. Frequently there are multiple exchanges of gas between the regions and sometimes plasmas are involved. A variety of materials have been developed for making pellicles including carbon nanotube (CNT) based pellicles, but most of the current materials including the CNT-pellicles have limited lifetimes due to reactions with the gases and/or plasmas that are involved in the processes. The interest in BNNT-based pellicles is that they BNNTs have thresholds for chemical reactions that are above the reactions driven by the gases and plasmas, and in addition, the BNNT pellicles can be heat treated to temperatures that will outgas or otherwise remove contaminants that may collect on the pellicles from gases and plasmas utilized in the lithographic processes.

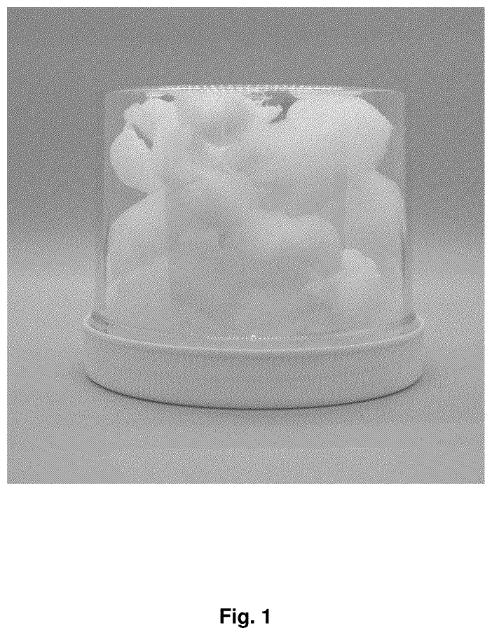

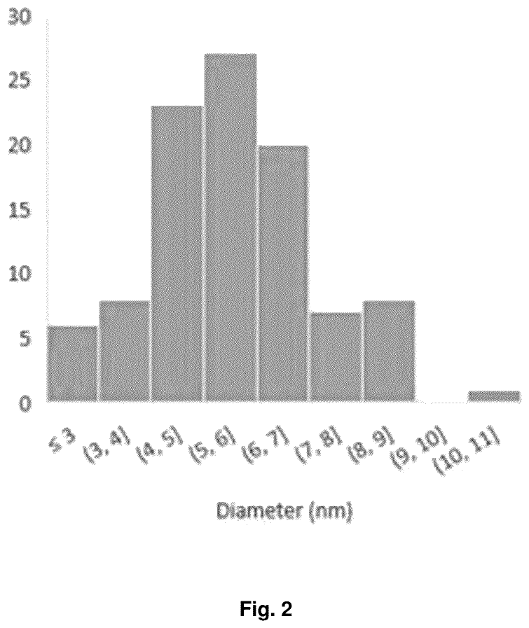

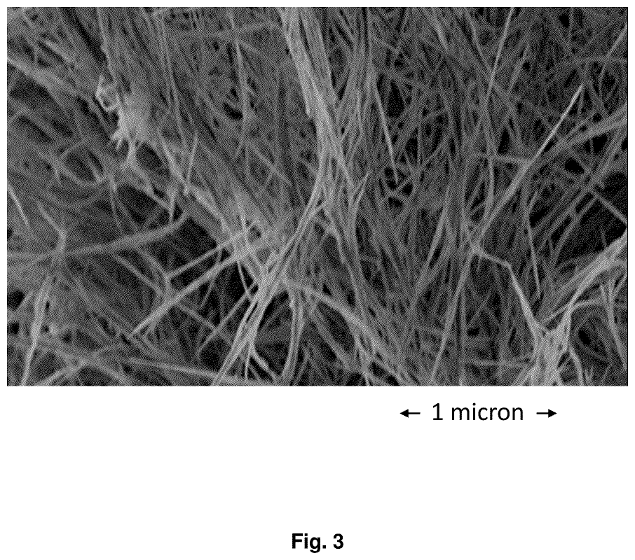

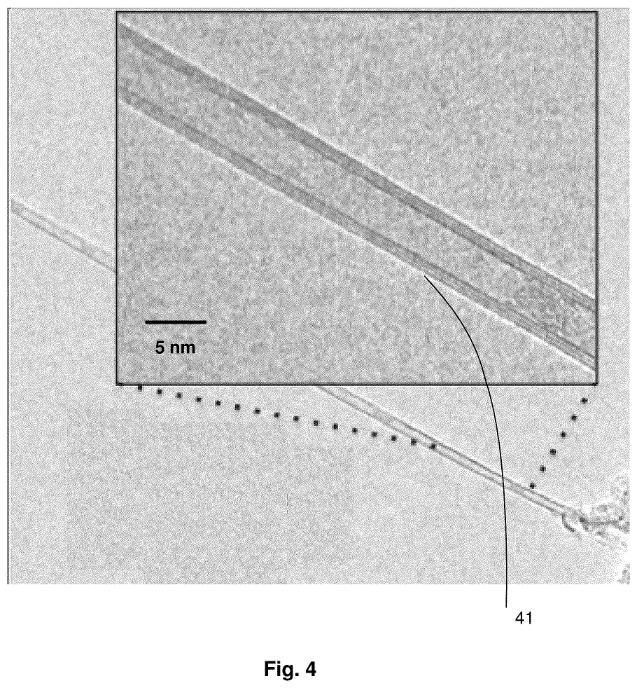

High quality BNNTs preferably have average length of 10-20 microns, with BNNTs ranging from 1.5 to 200 microns. Such BNNTs typically have diameters ranging from 2-6 nm and aspect ratios ranging from 300 to 100,000, though some BNNTs are beyond these regions. Embodiments of BNNT films, such as BNNT-based pellicles, are primarily composed of BNNT, with preferably less than 15 wt. % by mass of the BNNT film, and more preferably less than 12 wt. %, and more preferably less than 10 wt. %, and even more preferably less than 8 wt. %, being non-nanotube boron nitride (BN) or other non-BNNT materials, normally including BN species such as a-BN, BN nanocages and BN nanosheets. To achieve these parameters, high quality BNNTs may be synthesized as described in International Application PCT/US2019/034372, filed May 29, 2019, and International Application PCT/US2015/058615, filed Nov. 2, 2015, both of which are incorporated herein by reference in their entirety. It should be appreciated that high quality BNNTs may be synthesized by other high temperature, high pressure (HTP) processes known in the art, and preferably catalyst-free HTP synthesis processes. And, following initial synthesis, BNNTs may be and then refined to remove boron particulates. FIG. 1 shows an image of a refined BNNT puffball from BNNT, LLC (Newport News, VA), which contains more than 95 wt. % boron nitride as determined by thermogravimetric analysis. BNNT refinement processes, such as those described in International Application PCT/US2017/063729, filed Nov. 29, 2017, and incorporated by reference in its entirety, may be used to further change the relative amounts and size distributions of BNNT, amorphous boron particles, a-BN, BN nanocages, and BN nanosheets. FIG. 2 shows a distribution of high quality BNNT diameters following the purification described in International Application PCT/US2017/063729 for an embodiment required for the present approach. FIG. 3 shows an SEM of high quality BNNT collected from a solution. FIG. 4 is an image of a 3-wall BNNT have a 4.5 nm diameter.

In embodiments of the present approach, the BNNT film or membrane may be fabricated in part by employing modifications of methods known and used in the art, including, for example, vacuum filtration and casting of BNNT material from an optimized dispersion of high quality BNNTs. While both BNNT and CNT buckypapers can be made using such methods, the resulting buckypapers will not have the structure or strength to form a self-supporting film, without starting with sufficiently high quality BNNT and the optimized set of dispersion parameters described herein, and without achieving the 2D (x,y) in-plane alignment and compaction of the BNNTs as described herein. Typical buckypapers are too weak and optically opaque to function as a pellicle. The thickness of a buckypaper (z direction) is such that the BNNTs may have random orientation in the z-direction, reducing the 2D or x,y alignment. The following paragraphs describe how such methods may be advantageously modified to produce self-supporting thin film BNNT materials, such as BNNT-based pellicles.

Utilizing the methods described above, an initial BNNT material was prepared via the high temperature pressure (HTP) method, acquired from BNNT, LLC (Newport News, VA). The resultant material was mostly few-wall BNNTs with aspect ratios ranging from 300 to 100,000. plus a-BN, BN nanocages and BN nanosheets with the BNNTs making up approximately a third of the mass. The initial BNNT material was refined to remove boron particulates using the BNNT refinement process, described in International Application PCT/US2017/063729, filed Nov. 29, 2017, and incorporated by reference in its entirety. In particular in the first stage, the initial BNNT material was heated for up to 12 hours in a nitrogen and water vapor environment, at a temperature of about 500-650° C. Next in the second stage, amorphous boron particles, a-BN, BN nanocages, and BN nanosheets were removed by heating the BNNT material a temperature from 600° C. to 900° C. for up to 12 hours. The optimized BNNTs were then dispersed in an optimized system of solvent(s) and dispersing agents. The fraction of the solution with the optimized BNNT was then separated from the dispersion. The separated fraction of the dispersion was then deposited on a nylon substrate for subsequent filtration or casting process, resulting in a thin film BNNT material on the substrate.

In embodiments of the present approach, an optimized dispersion of high quality BNNTs, and preferably refined and purified BNNTs (also referred to as optimized BNNTs) in a solvent is prepared. In preferred embodiments, the BNNTs may be dispersed individually or into small agglomerates (e.g., where the size of the aggregate cannot be observed visually without magnification) in a solvent. BNNTs may be dispersed in a solvent by one or more dispersion methods, including for example, high speed stirring, bath sonication, probe sonication, and high shear mixing, in an appropriate media. The solvent may be polar, nonpolar, protic, aprotic, and combinations thereof, for example water, dimethylformamide, tetrahydrofuran, isopropyl alcohol, methanol, ethanol, diethyl ether, or a cyclic urea such as N,N′-dimethylpropyleneurea or 1,3-dimethylimidazolidin-2-one. A dispersion agent may be utilized in conjunction with a solvent. The dispersion agent may be a polymer or surfactant with cationic, anionic, or neutral charge, including for example, sodium dodecyl sulfate, sodium dodecylbenzene sulfonate, a poloxamer (such as Pluronic F108 or Pluronic F127), cetyltrimethyl ammonium bromide, or cetrimonium chloride. The dispersion agent may be added to a solvent in which it is soluble, at an appropriate concentration, which ranges from 0.1-10 wt. %. Persons having an ordinary level of skill in the art can determine the suitable concentration for a particular embodiment, without departing from the present approach. Generally, various concentrations may be used for a given solvent (e.g., 0.1, 1, and 10 wt. %), and the resulting thin film BNNT material may be analyzed to determine the suitability for the given embodiment. As an example, for a 0.1 mg/cm² film, the concentration may range from 0.001 mg/mL to 0.1 mg/mL. Another example, for a 0.01 mg/cm² film, the concentration may range from 0.1 μg/mL to 1 μg/mL.

The BNNTs may be directly added to the solvent or the solvent-dispersion agent mixture, and dispersed via one of the aforementioned mechanical means or other dispersal means known in the art. The concentration of BNNTs in the final dispersion may range from 0.01 μg/mL to 1 mg/mL, depending on the BNNT's solubility in the system. It should be appreciated that for some systems, the concentration of BNNTs in the dispersion may go beyond this range of concentration. The preferred concentration scales with areal density of the film and minimum volume of that concentration needed to wet out the membrane evenly for the size of the membrane. For example, if the BNNTs are highly soluble in the solvent system, a higher concentration of BNNT solution can be used to make the film than if the BNNT have a lower solubility in the solvent system. Depending on the properties of the BNNT (including for example, length, bundle size, purity, and wall number) and the method of purification, separation utilized, different solvent systems may be desired. In view of this potential for variability, it should be appreciated that for a given BNNT material and solvent system, the person having an ordinary level of skill in the art may identify the suitable BNNT concentration through routine experimentation using various concentrations (e.g., 0.1, 1, and 10 wt. %). The thin film BNNT material resulting from each concentration may be analyzed for suitability, through measuring properties of interest, e.g., density, thickness, tensile strength, and so on.

To achieve a thin film BNNT material, in some embodiments, a fraction of the solution with the optimized BNNTs, to be discussed, may be separated using separation methods known in the art, including for example, centrifugation, chromatography, or electrophoresis. For example, the fraction of the solution with the optimized BNNT may be composed of primarily individual BNNTs or small bundles of BNNTs. The optimized BNNT may also have desirable properties including tube lengths or minimization of BN particulates going into the pellicle fabrication. For example, a dispersion of BNNT may be centrifuged between 5-25000×g and the desired fraction, to be discussed, removed. The desired fraction may range from the top 5% of the volume of the dispersion or the top 75%, such as, for example, the top 5%, 10%, 15%, 20%, 25%, 30%, 35%, 40%, 45%, 50%, 55%, 60%, 65%, 70%, or 75%. The desired fraction may be selected based on apparent optical transparency and uniformity, versus the pellet. The desired fraction should comprise mostly individually dispersed nanotubes, or bundles of small numbers of nanotubes with the size of the aggregate of nanotubes being no more than 20 nm in one dimension. The dispersion may be evaluated by UV-visible absorption spectroscopy by means known to those skilled in the art and by SEM and TEM methods. The desired fraction of the solution with the optimized BNNTs is determined by correlating the optical transparency, UV-vis absorption spectroscopy, and the SEM and TEM information with the characteristics of the thin film to include thickness, areal density and strength. Other separation techniques commonly known to those in the art that have been used for carbon nanotubes may be applied without departing from the present approach.

In the present approach, the optimized BNNT solution is uniformly deposited on a porous substrate material. A sufficient volume of solution should be utilized so that the substrate is completely covered to avoid nonuniformities. The areal density of the film is controlled by volume and concentration of the dispersion deposited on the substrate. For filtration or casting, the substrate material is selected based on compatibility with the solvent(s) and surfactant(s) used, as well as the desired final properties of the BNNT film, including for example, surface roughness. The substrate may be composed of a hydrophilic or hydrophobic material, such as nylon, polyvinylidene fluoride, polypropylene, nitrocellulose, or cellulose. In the case of filtration, the substrate should be porous with pore sizes which typically range from 0.1 to 10 μm. In the case of vacuum or gravity filtration, the BNNT dispersion is filtered through the porous substrate, leaving BNNT in place on the substrate. In the case of casting or drawing, a draw bar is used to uniformly spread the BNNT dispersion onto the porous substrate. In some cases, a coagulant may be used to coagulate the BNNTs, densifying them into a film and to displace solvent, especially in the case of casting. The BNNT should be immiscible in the coagulant, which may be for example, acetone or water. In some cases, the BNNT film or membrane may then be rinsed with an appropriate solvent, such as those listed above, to remove impurities or dispersants such as surfactants and to further densify the film. The film may be dried before or after removing the BNNT film from the substrate. The BNNT film can be removed from the substrate directly by peeling or with the aid of vacuum or may be directly transferred to another substrate with the use of heat, pressure, or solvents. If dispersing agents are used, they may be removed by methods including rinsing, chemical reaction, or heating in various environments to degrade the dispersing agent at vacuum or at pressure. In some embodiments, the membrane may be densified by rolling or pressing to reduce internal scattering within the film before or after removing from the substrate to achieve films densities above 1 g/cm³ and as high as 2 g/cm³. In some embodiments, multiple layers of BNNTs with different areal or volumetric densities may be fabricated to provide additional properties including mechanical strength and transparency. The multiple layers may also be composed of different types of BNNTs, with different lengths and wall numbers.

In some embodiments, the BNNT film may be subjected to a high temperature treatment under vacuum to remove residual solvents and dispersants (such as surfactants). The temperature of the BNNT film heat treatment typically ranges from 150° C. to 600° C., and preferably 200° C. to 600° C. at pressures below 100 mTorr, for 0.5-5 h, and more preferably (but depending on the solvent(s) and dispersant(s) used, 350° C. to 600° C. at pressures below 100 mTorr, for 0.5-5 h, where the temperature and time are dependent on the residual solvents and dispersants, but may go beyond this range for specific solvents and dispersants.

The processes above fabricate films and membranes composed of BNNTs which may be preferentially aligned in the plane of the film or article, resulting from preferred maximized interaction of the BNNTs on the porous substrate. For example, 20-90% of the BNNTs may be longer than the thickness of the pellicle depending on the thickness of the pellicle and this by geometry may results in a partial 2D alignment of the BNNTs in the plane of the film. The film has a high transparency to visible, ultraviolet (UV), and extreme UV (EUV) light such that transmission at some or all of these wavelengths is greater than 80%, and in some embodiments, greater than 90%, and in some embodiments, greater than 95%.

In some embodiments, the thin film BNNT material is produced as a self-supporting material, requiring no additional substrate or support to retain its shape. The BNNT in the film may be bundled together to form a network which may result in a self-supporting film. As discussed above, the areal density of the BNNT film may range from 10⁻⁹ to 10⁻³g/cm² (1 nanogram to 1 milligram/cm²). The volumetric density of the film may range from 10⁻³ to 2 g/cm³, (1 milligram to 2 grams/cm³), depending on the desired final properties of the film. The surface of the film may be flat and smooth such that the variations in thickness are less than 1% of the average thickness, or may be relatively rough to include variations of up to 50% of the average thickness. The BNNT film may be porous to gases and ions including nitrogen, oxygen, water vapor, hydrogen, chlorides, fluorides, organic chemicals in general, noble gases, etc. where the open area of the film is greater than 50% of the total area of the film. These openings may be advantageously used to allow for gas cycling through the BNNT-based pellicle during lithography.

To achieve higher optical transparency and lower areal densities in thin film BNNTs, the BNNT film may have its areal density lowered by a process that etches away excess material. This step is performed using a similar process utilized to remove non-BNNT forms of BN present in the BNNT material going into the initial solution. More specifically, the BNNT film may be exposed to temperatures and environments which slowly etch the film, removing mass in a controlled manner. The temperatures can range from 700° C. to 1200° C. under gaseous environments such as air, nitrogen, wet steam, dry steam, oxygen, or helium, for example. The BNNT film may be mounted on a substrate that is compatible with the environment and temperature, including for example, silicon, quartz, or a metal such as stainless steel, nichrome or an Inconel® alloy (American Specialty Materials Corp., Miami, Florida), or it may be free standing. In some embodiments, the parameters are optimized to remove non-nanotube components and preserve the BNNTs in the film, and in some embodiments the parameters are optimized to non-selectively etch the film. As those having an ordinary level of skill in the art will appreciate, the exact conditions including etching times will depend on the detailed parameters and the characteristic of the BNNT going into the process. After the process, the 2D alignment of the BNNT within the film may be observed by interaction with plane polarized light.

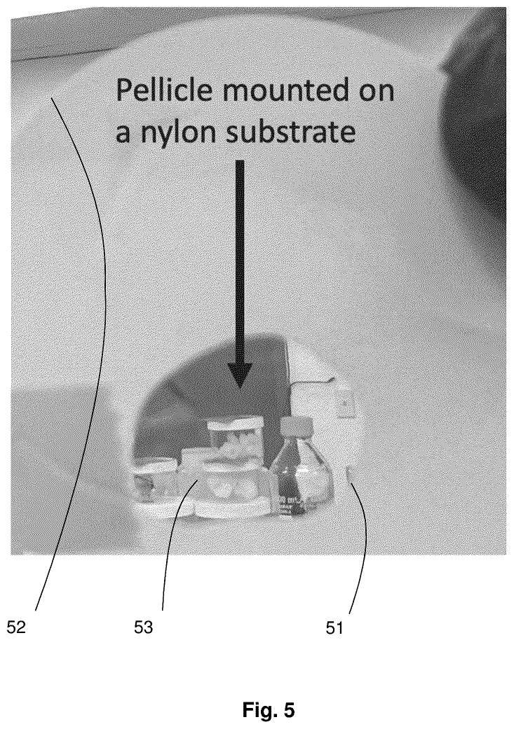

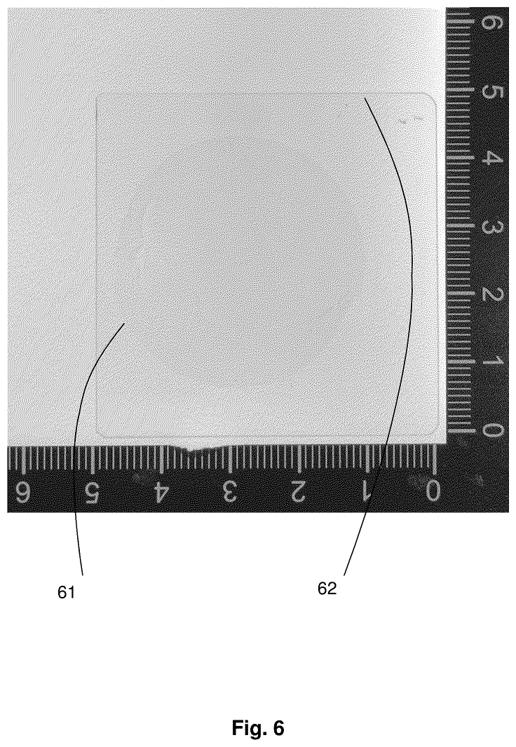

FIGS. 5 and 6 show examples of BNNT-based pellicles as described herein, made with the processes described herein. Utilizing the methods described above, the initial BNNT material was prepared via optimized conditions of the high temperature pressure (HTP) method, acquired from BNNT, LLC (Newport News, VA). The initial BNNT material was mostly few-wall BNNTs with aspect ratios ranging from 300 to 100,000 plus a-BN, BN nanocages and BN nanosheets with the BNNTs making up approximately a third of the mass. The initial BNNT material was refined to remove boron particulates, and purified to remove amorphous boron particles, a-BN, BN nanocages, and BN nanosheets as described above. This resulted in an optimized BNNT material, having nearly all non-BNNT species removed. After refinement and purification, the optimized BNNTs were dispersed in a solvent and dispersant, and then the thin film BNNT material was produced using a standard filtration process known in the art. In FIG. 5, a 1.5 cm diameter BNNT pellicle 51 is mounted on a hole in a nylon substrate 52 and a picture taken through the BNNT pellicle showing some BNNT puffballs in jars along with another jar 53. It should be appreciated that BNNT-based pellicle 51 is optically transparent, and as a result appears as merely a gap in nylon substrate 52.

Following preparation, the thin film BNNT material may be attached or mounted to a suitable frame. It should be appreciated that frame will depend on the particular embodiment. Example frames may be made of metal, silicon, or other materials. Depending on the frame, the mounting process may require use of an ionizer to prevent static charge accumulation. BNNT films can adhere to some frames through strong electrostatic forces. In some embodiments, an adhesive may be used to join the BNNT film periphery to the frame. In some embodiments, the frame may provide mechanical elements for attaching to the BNNT film, such as clamping the BNNT film between surfaces. In some embodiments, a solvent may be applied between the frame surface and BNNT film, and then the intersection of those surfaces baked (e.g., locally heated, or the entire frame and BNNT film may be baked) to remove the solvent and attach the BNNT film to the frame. A local air ionizer is typically used when handling the BNNT films.

Heat accumulation is often a concern in lithographic processes. Due to the high temperature performance of BNNTs, and high quality BNNT materials in particular, BNNT-based pellicles do not suffer the effects of over-heating as experiences with current pellicle materials. In addition, BNNTs have a very high (near 3000 W/m·K) heat conductivity for individual tubes. The individual nanotubes in thin film BNNT materials are preferentially aligned in the plane of the film and densely packed, resulting in good bulk thermal conductivity. The 2D alignment of BNNTs in a BNNT-based pellicle results in effective heat transfer away from the pellicle, towards film and frame edges, and/or radiated away. Additionally, thermal conductivity may be increased by densification of the BNNT film, such as through by solvent, pressing/rolling processes, and the like.

The resulting BNNT-based pellicle has improved mechanical, temperature, and chemical stability compared to current pellicles, including during EUV exposure and in the presence of free radicals produced during lithography. The BN structure in BNNTs is chemically stable, particularly compared to CNTs and other typical pellicle materials. Consequently, BNNT-based pellicles are minimally impacted by free radical production that make take place from the processing from light and chemicals in the systems where the BNNT pellicles are deployed.

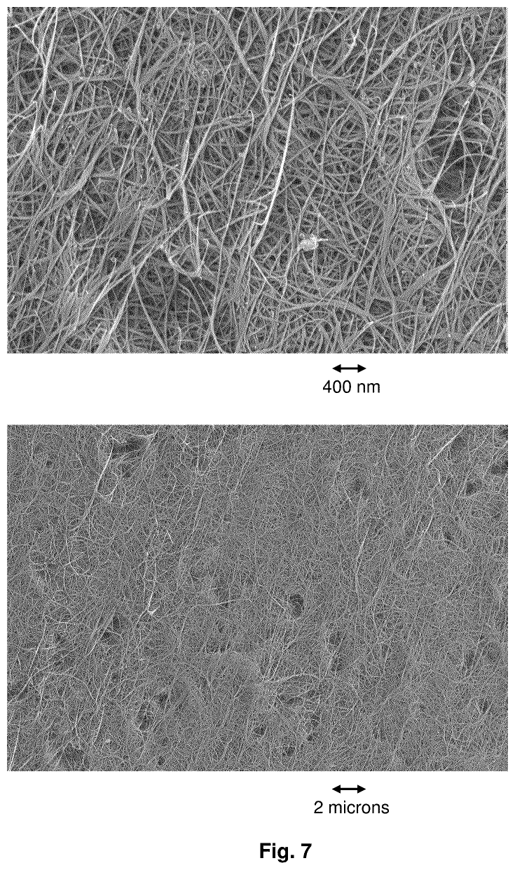

FIG. 6 shows a 3 cm diameter BNNT-based pellicle 61 with a clear plastic square 62 holding the BNNT-based pellicle 61 in place over a white paper background. Scale (inches) provided for reference. FIG. 7 shows SEM images of the surface of a 400 microgram/cm² areal density BNNT pellicle where it is observed that the material is almost exclusively BNNTs.

The purified high quality BNNT material placed into solution and the final BNNT-based pellicle typically has a surface area ranging from 200-450 m²/g as determined by BET though in some embodiments the surface area may be beyond this range. For some embodiments, the BNNT-based pellicles can also be coated in the same manners as described in U.S. patent application Ser. No. 17/139,431, filed Dec. 31, 2020 wherein reactive monomers are coated onto BNNTs in a heated chamber, International Patent Application PCT/US2021/014288, filed Jan. 21, 2021 wherein solutes are deposited onto the BNNTs by evaporating away the solvent leaving the solute material coating the BNNTs, U.S. Pat. No. 11,362,400, filed Aug. 2, 2018 wherein the BNNTs are coated by solutes evaporations and alternatively physical vapor deposition (PVD), and U.S. patent application Ser. No. 16/349,512, filed May 13, 2019 wherein the inclusion of metals is discussed, the entire contents of which are incorporated by reference in their entirety. For some BNNT-based pellicle embodiments, having coatings on the BNNTs may be an advantage for using the BNNT pellicle as a scaffold for holding the coating material thereby achieving very thin films of the coating material that are porous to the flow of gases through the film as are the films described herein. This greatly increases the surface area of the coating material. An example is where the BNNT pellicle is the scaffold support for what would otherwise not be a thin film of material well exposed the surrounding gas. An example is a thin coating of platinum particles deposited on the BNNTs would allow for a high temperature gas to both flow through the film while catalytically interacting with the platinum. Consequently, the BNNT thin films and pellicles may serve as the foundation for a variety of membranes.

Sample embodiments of the BNNT pellicles as described herein have the following properties: They are made of over 80 wt. % BNNTs, and preferably over 85 wt. % BNNTs, and more preferably over 90 wt. % BNNTs, and even more preferably 95 wt. % BNNTs, wherein over 50% of the BNNTs, and preferably over 60% of the BNNTs, and more preferably over 70% of the BNNTs, have 2-walls or 3-walls with average tube lengths in excess of 1.0 microns, and preferably over 1.5 microns, and preferably with less than 5 wt. % non-BNNT material; they are self-supporting over areas in excess of 3 cm in diameter; they are greater than 80%, and preferably greater than 85%, and more preferably greater than 90%, optically transparent to visible light; they have areal densities ranging from 1-500 μg/cm²; and they have volume densities ranging from 0.01-1 g/cm³. Embodiments of the thin film BNNT material may have a single layer thickness between 0.1 micron and 300 microns, and in some embodiments the single layer thickness may be between 0.2 micron and 100 microns.

It should be appreciated that the number of walls and nanotube diameter may be evaluated by transmission electron microscopy (TEM). The number of walls in the visible BNNTs for a randomly collected selection may be counted, and the diameter may be measured, using the same image. The wall and diameter evaluation may take place while BNNTs are in solution or sampled from a solution, prior to forming the film. Alternatively, a sample may be removed from a film and dispersed in solution for wall and diameter evaluation.

Scanning electron microscopy (SEM) may be used to evaluate the relative percent impurities, including h-BN as nanosheets, nanocages, a-BN, c-BN, and boron particulates by counting the impurities in a randomly collected selection of samples.

A combined analysis of 10 representative HR-SEM micrographs at 20,000× magnification, and 20 representative TEM micrographs at 0.2 nm resolution of a BNNT sample, can be used to determine the relative fraction of BNNTs versus other h-BN nano-allotropes in the refined BNNT material.

It should be appreciated that the present approach is not limited to the specific embodiments disclosed. The person having an ordinary level of skill in the art will recognize that the optimum BNNTs for a given BNNT material, as well as the desired fraction, will depend largely on the starting BNNT material and the solvent system used for the specific embodiment. It should be appreciated that numerous such embodiments are contemplated under the present approach.

Unless otherwise stated, the term “about,” as used herein when referring to a measurable value, such as, for example, an amount or concentration and the like, is meant to encompass variations of ±20%, ±10%, ±5%, ±1%, ±0.5%, or even ±0.1% of the specified amount. A range provided herein for a measurable value may include any other range and/or individual value within the stated range.

The terminology used herein is for the purpose of describing particular embodiments only and is not intended to be limiting of the approach. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The present approach may be embodied in other specific forms without departing from the spirit or essential characteristics thereof. The disclosed embodiments are therefore to be considered in all respects as illustrative and not restrictive, the scope of the present approach being indicated by the claims of the application rather than by the foregoing description, and all changes which come within the meaning and range of equivalency of the claims are therefore intended to be embraced therein. One of ordinary skill in the art should appreciate that numerous possibilities are available, and that the scope of the present approach is not limited by the embodiments described herein.

What is claimed is:

1. A thin film boron nitride nanotube (BNNT) material comprising at least 80 wt. % BNNTs, over 50% of the BNNTs have 2-walls or 3-walls and average tube lengths in excess of 1.0 microns, the thin film BNNT material having a film thickness between 0.1 micron and 300 microns.

2. The thin film BNNT material of claim 1, wherein the thin film BNNT material comprises at least 95 wt. % BNNTs.

3. The thin film BNNT material of claim 1, wherein the thin film BNNT material has a film thickness between 0.02 micron and 100 microns.

4. The thin film BNNT material of claim 1, wherein over 70% of the BNNTs in the thin film BNNT material have 2-walls or 3-walls.

5. The thin film BNNT material of claim 1, wherein the BNNTs in the thin film BNNT material have an average tube length of at least 1.5 microns.

6. The thin film BNNT material of claim 1, wherein the thin film BNNT material is self-supporting over an area at least 3 cm in diameter.

7. The thin film BNNT material of claim 1, wherein the thin film BNNT material is at least 80% optically transparent to visible light.

8. The thin film BNNT material of claim 1, wherein the thin film BNNT material is at least 90% optically transparent to visible light.

9. The thin film BNNT material of claim 1, wherein the BNNT material has an areal density of between 1 μg/cm² and 500 μg/cm².

10. The thin film BNNT material of claim 1, wherein the BNNT material has a volume density of between 0.01 g/cm³ and 1 g/cm³.

11. The thin film BNNT material of claim 1, comprising a plurality of layers of BNNT material.

12. A BNNT-based pellicle comprising a thin film BNNT material of claim 1, attached to a frame.

13. A method for producing a thin film boron nitride nanotube (BNNT) material, the method comprising:
preparing a refined BNNT material by removing boron particulates from an initial BNNT material;
preparing a purified BNNT material by removing amorphous boron particles, a-BN, BN nanocages, and BN nanosheets from the refined BNNT material;
forming a BNNT dispersion by dispersing the purified BNNT material in a solvent;
forming an optimized BNNT solution by separating a top fraction of the BNNT dispersion;
forming a thin film of BNNT on a substrate by depositing the optimized BNNT solution on the substrate and removing the solvent.

14. The method for producing a thin film BNNT material of claim 13, wherein removing boron particulates from an initial BNNT material comprises heating the initial BNNT material in a nitrogen and water vapor environment, at a temperature of about 500-650° C.

15. The method for producing a thin film BNNT material of claim 13, wherein removing amorphous boron particles, a-BN, BN nanocages, and BN nanosheets from the initial BNNT material comprises heating the refined BNNT material to a temperature from 650° C. to 900° C.

16. The method for producing a thin film BNNT material of claim 13, wherein the top fraction comprises the top 75% of the volume of the BNNT dispersion.

17. The method for producing a thin film BNNT material of claim 13, wherein the top fraction comprises the top 5% of the volume of the BNNT dispersion.

18. The method for producing a thin film BNNT material of claim 13, wherein the thin film of BNNT has a thickness between 0.1 micron and 300 microns.

19. The method for producing a thin film BNNT material of claim 13, wherein the thin film of BNNT has a thickness between 0.2 micron and 100 microns.

20. The method for producing a thin film BNNT material of claim 13, further comprising forming a plurality of thin film layers on the substrate.

21. A method for producing a thin film BNNT pellicle, the method comprising:
preparing a BNNT solution from
a BNNT material having at least 80 wt. % BNNTs, over 50% of the BNNTs have 2-walls or 3-walls and average tube lengths in excess of 1.0 microns and
a solvent;
forming a thin film from the BNNT solution; and
mounting the thin film.

22. The method of claim 21, wherein the thin film has a film thickness from

0. 1 micron to 300 microns.

23. The method of claim 21, wherein the thin film has a film thickness from 0.2 micron to 100 microns.
